(19) United States
(12) Patent Application Publication
(10) Pub. No.: US 2024/0188337 A1
(43) Pub. Date: Jun. 6, 2024

(54) DISPLAY PANEL, DISPLAY DEVICE, AND METHOD OF PREPARING THE SAME

(71) Applicant: Yungu (Gu’an) Technology Co., Ltd., Langfang (CN)

(72) Inventors: Zhimin YAN, Langfang (CN); Siming GAO, Langfang (CN)

(73) Assignee: Yungu (Gu’an) Technology Co., Ltd., Langfang (CN)

(21) Appl. No.: 18/439,074

(22) Filed: Feb. 12, 2024

Related U.S. Application Data
(63) Continuation of application No. PCT/CN2023/084304, filed on Mar. 28, 2023.

(30) Foreign Application Priority Data
Jun. 29, 2022 (CN) 202210750958.7
Nov. 21, 2022 (CN) 202211544887.1

(51) Int. Cl. H10K 59/122; H10K 59/126; H10K 102/00

(52) U.S. Cl. CPC H10K 59/122; H10K 59/126; H10K 2102/3031

(57) ABSTRACT

A display panel, a display device, and a preparing method of a display panel. The display panel includes an array substrate; a first electrode layer located on a side of the array substrate, the first electrode layer includes a pixel electrode. A pixel definition layer located on a side of the first electrode layer away from the array substrate, the pixel definition layer includes an isolation portion and a pixel opening surrounded by the isolation portion. A second electrode layer located on a side of the pixel definition layer away from the array substrate, the second electrode layer includes a second electrode and an opening, the second electrode includes a body portion and an edge portion arranged as extending from the body portion and toward the opening.

### CROSS-REFERENCE TO RELATED APPLICATION

The present application is a continuation of International Application No. PCT/CN2023/084304 filed on Mar. 28, 2023, which claims priority to Chinese Patent Application No. 202210750958.7, filed on Jun. 29, 2022 and entitled “DISPLAY PANEL, DISPLAY DEVICE, AND PREPARING METHOD OF DISPLAY PANEL”, and Chinese Patent Application No. 202211544887.1, filed on Nov. 21, 2022 and entitled “DISPLAY PANEL, DISPLAY DEVICE, AND PREPARING METHOD OF DISPLAY PANEL”, both of which are hereby incorporated by reference in their entireties.

### TECHNICAL FIELD

The present application relates to a technical field of display, and particularly relates to a display panel, a display device, and a method of preparing the same.

### BACKGROUND

With the rapid development of electronic devices, the user's requirements for display effect are becoming higher and higher, thereby causing the screen display of the electronic devices to receive more and more attention from the industry.

In order to improve the display effect of the screen of the electronic device, the existing technology will pattern the cathode when preparing the screen of the electronic device, such as etching the cathode by using laser etching method, thereby improving the transmittance of the screen. However, during the process of etching the cathode, the cathode material generally peels in the etching region, which affects the subsequent packaging.

### SUMMARY

The embodiments of the present application provide a display panel, a display device, and a preparing method of a display panel, which can realize that at least a part of the display panel is transparent and displayable, thereby facilitating the under-screen integration of the photosensitive components.

In a first aspect, an embodiment of the present application provides a display panel, including: an array substrate; a first electrode layer located on a side of the array substrate, wherein the first electrode layer includes a pixel electrode; a pixel definition layer located on a side of the first electrode layer away from the array substrate, wherein the pixel definition layer includes an isolation portion and a pixel opening surrounded by the isolation portion; a second electrode layer located on a side of the pixel definition layer away from the array substrate, wherein the second electrode layer includes a second electrode and an opening, the second electrode includes a body portion and an edge portion arranged as extending from the body portion and toward the opening; wherein the pixel definition layer further includes an opening hole located at the isolation portion, at least a part of the array substrate is exposed by the opening hole, and the edge portion contacts the at least a part of the array substrate exposed by the opening hole.

In a second aspect, an embodiment of the present application provides a preparing method of a display panel, including: preparing an array substrate, wherein the array substrate includes a first blocking layer, the first blocking layer includes a first through hole; preparing a first conductive material layer on the array substrate and patterning the first conductive material layer to obtain a first electrode layer including a pixel electrode; preparing a pixel definition layer on a side of the first electrode layer away from the array substrate, wherein the pixel definition layer includes an isolation portion and a pixel opening surrounded by the isolation portion; patterning the isolation portion of the pixel definition layer to form an opening hole, wherein the opening hole penetrates through the isolation portion, and at least a part of the array substrate is exposed by the opening hole; preparing a second conductive material layer on a side of the pixel definition layer away from the array substrate; laser-etching the second conductive material layer from a side of the array substrate away from the pixel definition layer, wherein laser light passes through the first through hole and etches the second conductive material layer to obtain an opening, and an unetched area of the second conductive material layer is used as a second electrode.

In a third aspect, an embodiment of the present application provides a display panel, including: an array substrate; a first electrode layer located on a side of the array substrate, wherein the first electrode layer includes a pixel electrode; a pixel definition layer located on a side of the first electrode layer away from the array substrate, wherein the pixel definition layer includes an isolation portion and a pixel opening surrounded by the isolation portion; a second electrode layer located on a side of the pixel definition layer away from the array substrate, wherein the second electrode layer includes a second electrode and an opening; wherein the second electrode includes a body portion and an edge portion arranged as extending from the body portion and toward the opening, the body portion contacts the pixel definition layer, the edge portion contacts the array substrate or the pixel definition layer, and an adhesion force between the edge portion and the array substrate or the pixel definition layer is greater than an adhesion force between the body portion and the pixel definition layer.

In a fourth aspect, an embodiment of the present application provides a display panel, including: an array substrate, wherein the array substrate includes a first blocking layer, and the first blocking layer includes a first through hole; a first electrode layer located on a side of the array substrate, wherein the first electrode layer includes a pixel electrode; a pixel definition layer located on a side of the first electrode layer away from the array substrate, wherein the pixel definition layer includes an isolation portion and a pixel opening surrounded by the isolation portion; a second electrode layer located on a side of the pixel definition layer away from the array substrate, wherein the second electrode layer includes a second electrode and an opening, the second electrode includes a body portion and an edge portion arranged as extending from the body portion and toward the opening; wherein an orthographic projection of the first through hole in a thickness direction of the display panel overlaps an orthographic projection of the opening in the thickness direction of the display panel, a distance between the edge portion and the first blocking layer in the thickness direction of the display panel is less than a distance between the body portion and the first blocking layer in the thickness direction of the display panel.

In a fifth aspect, an embodiment of the present application provides a display device, including the display panel in any above embodiment.

According to the display panel provided by the embodiments of the present application, the display panel includes the array substrate, and the first electrode layer, the pixel definition layer, and the second electrode layer disposed on the array substrate. The first electrode layer includes the pixel electrode, and the second electrode layer includes the second electrode and the opening. The array substrate includes the first blocking layer, the first blocking layer includes the first through hole, and the first blocking layer is disposed within the array substrate, which can avoid affecting the display of the display panel. In the preparation process of the second electrode layer, the first blocking layer can be utilized as a mask plate, and the opening can be formed by emitting laser light from a side of the array substrate away from the first electrode layer through the first through hole toward the second electrode layer. Through the above structural design, the opening is disposed in the second electrode layer, which can reduce the distribution area of the second electrode, thereby improving the light transmittance of the display panel, and enabling the integration of the photosensitive component on the non-display side of the display panel, that is, facilitating the under-screen integration of the photosensitive component. In the embodiments of the present application, on the one hand, due to the existence of the first blocking layer, the distance between the first blocking layer and the second electrode layer is relatively small, the diffraction effect produced by the laser is relatively small, and in the process of laser etching, it is possible to effectively avoid the fold-over of the edge of the second electrode toward the opening caused by laser diffraction from affecting the subsequent encapsulation effect; on the other hand, it is possible to perform a roughening treatment on the surface of the array substrate exposed by the opening hole, so as to increase the roughness of the surface of the array substrate exposed by the opening hole, which can increase the adhesion force between the edge portion of the second electrode and the at least a part of the array substrate exposed by the opening hole, and can better ameliorate the problem of the upturning of the edge of the second electrode toward the opening.

### BRIEF DESCRIPTION OF THE DRAWINGS

Other features, purposes and advantages of the present application will be more apparent by reading the following detailed description of the non-restrictive embodiments with reference to the drawings. Here, the same or similar reference numbers indicate the same or similar features, and the drawings are not drawn to actual scale.

FIG. 1 is a schematic structural view of a display panel provided by an embodiment of a first aspect of the present application;

FIG. 2 is a cross-sectional view at A-A in FIG. 1;

FIG. 3 is a cross-sectional view at A-A in FIG. 1 in another embodiment;

FIG. 4 is a local enlarged schematic structural view at Q in FIG. 1;

FIG. 5 is a cross-sectional view at A-A in FIG. 1 in yet another embodiment;

FIG. 6 is a cross-sectional view at A-A in FIG. 1 in yet another embodiment;

FIG. 7 is a cross-sectional view at A-A of FIG. 1 in yet another embodiment;

FIG. 8 is a cross-sectional view at A-A of FIG. 1 in yet another embodiment;

FIG. 9 is a local enlarged schematic structural view at Q in FIG. 1 in yet another embodiment;

FIG. 10 is a cross-sectional view at A-A in FIG. 1 in yet another embodiment;

FIG. 11 is a local enlarged schematic structural view at Q in FIG. 1 in yet another embodiment;

FIG. 12 is a schematic flow diagram of a method of preparing a display panel provided by an embodiment of a second aspect of the present application.

### DETAILED DESCRIPTION

Features and exemplary embodiments of various aspects of the present application are described in detail below. In order to clarify the purposes, technical solutions and advantages of the present application, the present application will be further described in detail below in combination with the accompanying drawings and specific embodiments. It should be understood that the specific embodiments described herein are intended to interpret the present application and not to limit the present application. For those skilled in the art, the present application may be practiced without some of these specific details. The following description of the embodiments is merely to provide a better understanding of the present application by illustrating examples of the present application.

In an electronic device such as a cell phone and a tablet computer, it is necessary to integrate a photosensitive component, such as a front-facing camera, an infrared light sensor, a proximity light sensor, and the like, on the side where the display panel is provided. In some embodiments, a transparent display region may be provided on the above electronic device, and the photosensitive component may be provided at the back of the transparent display region, so that a full-screen display of the electronic device can be realized under the condition of ensuring that the photosensitive component works properly.

In order to improve the light transmittance of the transparent region, in some related techniques, the common electrodes are patterned. The common electrodes are made to form hollows in the transparent region of the display panel, so as to improve the light transmittance of the common electrodes, which in turn can improve the light transmittance of the transparent region of the display panel. In the related techniques, laser ashing and other means are generally used to realize the patterning of the common electrodes.

However, in the related technology, under a condition that the laser ashing is utilized to pattern the common electrodes, usually after forming an array substrate, a light-emitting layer, and the common electrodes on the substrate, laser irradiation is performed on the common electrodes from a side of the substrate away from the array substrate, and laser etching is performed on the common electrodes by utilizing a light shielding metal layer within the array substrate as a mask plate, thereby realizing the patterning of the common electrode. The inventor found that after laser etching of the common electrodes to realize the patterning, the edges of the common electrodes are easy to be inwardly turned, which affects the subsequent processes such as thin film encapsulation, and affects the reliability of the encapsulation process.

In order to solve the above problem, the embodiments of the present application provide a display panel, a display device, and a preparing method of a display panel, and various embodiments of the display panel, the display device, and the preparing method of the display panel will be described below in connection with the accompanying drawings.

The embodiments of the present application provide a display panel, which may be an Organic Light Emitting Diode (OLED) display panel.

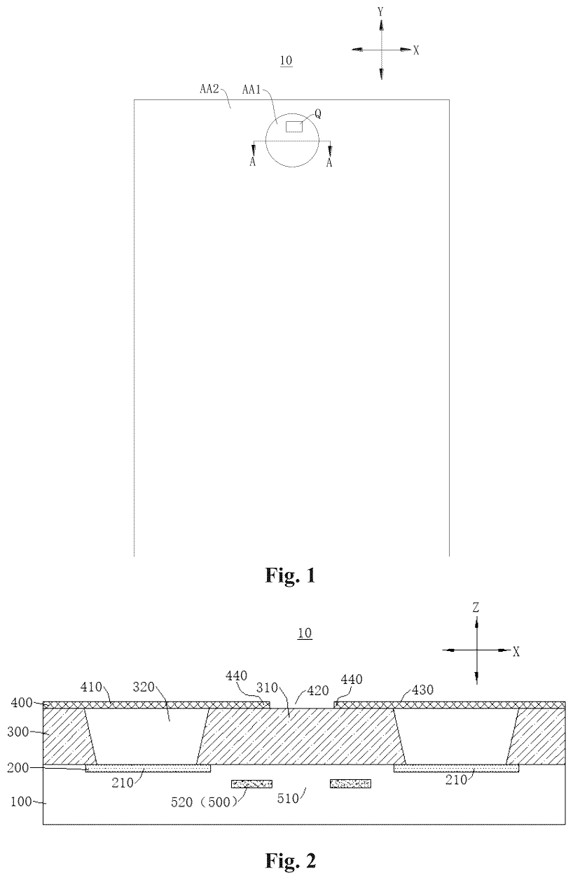

Referring together to FIGS. 1 and 2, FIG. 1 is a schematic structural view of a display panel provided by an embodiment of a first aspect of the present application, and FIG. 2 is a cross-sectional view at A-A in FIG. 1.

As shown in FIGS. 1 and 2, the display panel 10 provided by the embodiment of the first aspect of the present application includes an array substrate 100, and a first electrode layer 200, a pixel definition layer 300, and a second electrode layer 400 disposed on the array substrate 100. The array substrate 100 includes a first blocking layer 500, the first blocking layer 500 includes a first through hole 510. The first electrode layer 200 is located on a side of the array substrate 100, and the first electrode layer 200 includes a pixel electrode 210. The pixel definition layer 300 includes an isolation portion 310 and a pixel opening 320 surrounded by the isolation portion 310, and at least a part of the pixel electrodes 210 are exposed by the pixel opening 320. The second electrode layer 400 is located on a side of the pixel definition layer 300 away from the array substrate 100, the second electrode layer 400 includes a second electrode 410 and an opening 420, the second electrode 410 includes a body portion 430 and an edge portion 440 arranged as extending from the body portion 430 and toward the opening 420, and the orthographic projections of the opening 420 and the pixel electrode 210 on the array substrate 100 are staggered. The orthographic projection of the first through hole 510 in the thickness direction of the display panel overlaps the orthographic projection of the opening 420 in the thickness direction of the display panel.

In some optional embodiments, as shown in FIG. 2, the body portion 430 of the second electrode 410 contacts the pixel definition layer 300, the edge portion 440 of the second electrode 410 also contacts the pixel definition layer 300, and an adhesion force between the edge portion 440 and the pixel definition layer 300 is greater than an adhesion force between the body portion 430 and the pixel definition layer 300. Optionally, a plasma bombardment treatment may be performed on a part of the surface of the pixel definition layer 300 corresponding to the edge portion 440, such that a roughness of the part of the surface of the pixel definition layer 300 corresponding to the edge portion 440 rises, thereby causing the adhesion force between the edge portion 440 and the pixel definition layer 300 to be greater than the adhesion force between the body portion 430 and the pixel definition layer 300.

According to the display panel 10 of the embodiment of the present application, the display panel 10 includes the array substrate 100, and the first electrode layer 200, the pixel definition layer 300, and the second electrode layer 400 disposed on the array substrate 100. The first electrode layer 200 includes the pixel electrode 210, the second electrode layer 400 includes the second electrode 410 and the opening 420, and the second electrode 410 includes the body portion 430 and the edge portion 440 arranged as extending from the body portion 430 and toward the opening 420. The first blocking layer 500 includes the first through hole 510, and the first blocking layer 500 is disposed within the array substrate 100, which can avoid affecting the display of the display panel 10. In the preparation process of the second electrode layer 400, the opening 420 can be formed by emitting laser light from a side of the array substrate 100 away from the first electrode layer 200 through the first through hole 510 toward the second electrode layer 400, and the first blocking layer 500 serves as a mask plate in the above process. Through the above structural design, on the one hand, the opening 420 is disposed in the second electrode layer 400, which can reduce the distribution area of the second electrode 410, thereby increasing the light transmittance of the display panel 10, and enabling the integration of the photosensitive component on the non-display side of the display panel 10, that is, facilitating the under-screen integration of the photosensitive component. On the other hand, due to the existence of the first blocking layer 500, the distance between the first blocking layer 500 and the second electrode layer 400 is relatively small, the diffraction effect produced by the laser is relatively small, and in the process of laser etching, it is possible to effectively avoid the fold-over of the edge of the second electrode 410 toward the opening 420 caused by laser diffraction from affecting the encapsulation effect of the subsequent encapsulation process.

The array substrate 100 may also be arranged in a variety of ways. For example, the array substrate 100 may include a substrate and a film layer structure disposed on the substrate, such as a TFT array layer, a planarization layer, and the like. Alternatively, the array substrate 100 is the substrate. Alternatively, the array substrate 100 also includes a substrate, and a buffer layer and a support plate disposed on a side away from the substrate. The array substrate 100 in the present application may be a multi-film layer structure.

For example, the first electrode layer 200 is an anode layer, and the second electrode layer 400 is a cathode layer. When the first electrode layer 200 and the second electrode layer 400 are utilized to drive the light-emitting unit within the pixel opening 320 to emit light, the pixel electrode 210 in the first electrode layer 200 serves as the anode, and the second electrode 410 in the second electrode layer 400 serves as the cathode.

Optionally, in the first electrode layer 200, the pixel electrode 210 at least partially overlaps the pixel opening 320 along the thickness direction Z of the display panel 10.

Please continue to refer to FIG. 1, in some optional embodiments, the display panel 10 includes a first display region AA1, a second display region AA2, and a non-display region surrounding the first display region AA1 and the second display region AA2. The light transmittance of the first display region AA1 is greater than the light transmittance of the second display region AA2.

In the present application, optionally, the light transmittance of the first display region AA1 is greater than or equal to 15%. To ensure that the light transmittance of the first display region AA1 is greater than 15%, or even greater than 40%, or even a higher light transmittance, the light transmittance of each functional film layer of the display panel 10 in this embodiment is greater than 80%, or even the light transmittances of at least some of the functional film layers are greater than 90%.

According to the display panel 10 of the embodiments of the present application, the light transmittance of the first display region AA1 is greater than the light transmittance of the second display region AA2, so that the display panel 10 can integrate a photosensitive component on the back of the first display region AA1, thereby realizing the under-screen integration of the photosensitive component such as a camera. At the same time, the first display region AA1 is capable of displaying a picture, which improves the display area of the display panel 10, and realizes the full-screen design of the display device.

Optionally, the opening 420 of the second electrode layer 400 may be located in the first display region AA1 to improve the light transmittance of the first display region AA1. In other embodiments, the opening 420 of the second electrode layer 400 may also be located in both the first display region AA1 and the second display region AA2 to improve the light transmittance of the entire display region.

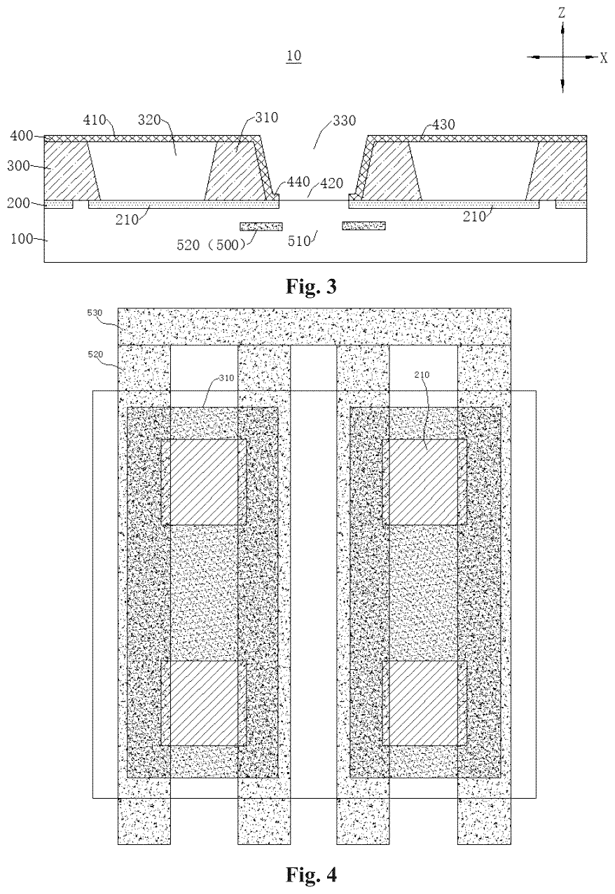

Referring to FIGS. 3 and 4 together, FIG. 3 is a cross-sectional view at A-A in FIG. 1 in another embodiment; and FIG. 4 is a local enlarged schematic structural view at Q in FIG. 1.

In some optional embodiments, the pixel definition layer 300 further includes an opening hole 330 located at the isolation portion 310, and an orthographic projection of the opening 420 on the array substrate 100 is located within an orthographic projection of the opening hole 330 on the array substrate 100.

In these optional embodiments, when preparing the second electrode layer 400 on the pixel definition layer 300, a second conductive material layer is firstly formed on the pixel definition layer 300, and then the second conductive material layer is patterned to form the second electrode layer 400. The second conductive material layer can be deposited directly on the array substrate 100 within the opening hole 330, thereby further reducing the distance between the second electrode layer 400 and the first blocking layer 500.

Optionally, the opening hole 330 penetrates through the isolation portion 310. So that, better laser ashing of the second electrode layer 400 can be performed by the laser light through the opening hole 330.

Optionally, the pixel electrode 210 is formed by a wet etching process. The pixel electrode 210 is prepared by the wet etching process, so that the roughness of the upper surface of the array substrate 100 rises, and at the same time, the opening hole 330 penetrates through the isolation portion 310, so that the roughness of the upper surface of the array substrate 100 at the opening hole 330 rises, and the second conductive material layer can be directly deposited on the array substrate 100 within the opening hole 330. Thus, the adhesion force between the second electrode layer 400 and the upper surface of the array substrate 100 is stronger, and it is difficult for the second electrode 410 of the second electrode layer 400 to undergo edge upturning.

Optionally, the opening hole 330 penetrates through the isolation portion 310, at least a part of the array substrate 100 is exposed by the opening hole 330, and the edge portion 440 of the second electrode 410 directly contacts the upper surface of the at least a part of the array substrate 100 exposed by the opening hole 330, so that the distance between the first blocking layer 500 and the edge portion 440 of the second electrode 410 is relatively small, and it is possible to avoid the fold-over of the edge portion 440 of the second electrode 410 toward the opening 420 caused by laser diffraction from affecting the encapsulation effect of the subsequent encapsulation process. When the first blocking layer 500 is utilized for the laser etching ashing of the second conductive material layer, the opening 420 can be formed in the region corresponding to the opening hole 330, that is, the opening 420 is formed in a portion of the second conductive material layer closer to the first blocking layer 500, which can better ameliorate the problem of the upturning of the edge portion 440 of the second electrode 410 toward the opening 420, and can better ameliorate the effect of the upturning of the edge portion 440 of the second electrode 410 toward the opening 420 on the subsequent encapsulation process.

Optionally, as shown in FIGS. 1 to 5, the array substrate 100 includes a planarization layer 110, the pixel electrode 210 is disposed on a side of the planarization layer 110 close the second electrode layer 400, at least a part of the planarization layer 110 is exposed by the opening hole 330, and the edge portion 440 of the second electrode 410 directly contacts the at least a part of the planarization layer 110 exposed by the opening hole 330. In these embodiments, the surface of the planarization layer 110 exposed by the opening hole 330 can be roughened to improve the roughness of the surface of the planarization layer 110 exposed by the opening hole 330, which can increase the adhesion force between the edge portion 440 of the second electrode 410 and the at least a part of the planarization layer 110 exposed by the opening hole 330, and can better ameliorate the problem of the upturning of the edge portion 440 of the second electrode 410 toward the opening 420.

In these embodiments, the body portion 430 of the second electrode 410 contacts the pixel definition layer 300, and the adhesion force between the edge portion 440 of the second electrode 410 and at least a part of the array substrate exposed by the opening hole 330 is greater than the adhesion force between the body portion 430 and the pixel definition layer 300. Optionally, the body portion 430 of the second electrode 410 contacts the pixel definition layer 300, and the adhesion force between the edge portion 440 of the second electrode 410 and at least a part of the planarization layer 110 exposed by the opening hole 330 is greater than the adhesion force between the body portion 430 and the pixel definition layer 300.

Optionally, the planarization layer 110 is disposed between the first blocking layer 500 and the pixel definition layer 300, the pixel electrode 210 is disposed on the side of the planarization layer 110 toward the pixel definition layer 300, and the edge portion 440 of the second electrode 410 located in the opening hole 330 directly contact the upper surface of the planarization layer 110.

In these optional embodiments, the first electrode layer 200 is arranged on the planarization layer 110. When the pixel electrode 210 is formed by patterning, for example, when the pixel electrode 210 is formed by removing a part of the conductive material using a wet etching process, the etching solution used in the wet etching process contacts the surface of the planarization layer 110 at other locations, thereby increasing the roughness of the upper surface of the planarization layer 110 at the opening hole 330. The edge portion 440 of the first electrode 410 located at the opening hole 330 contacts the upper surface of the planarization layer 110, so that the adhesion force between the second electrode layer 400 and the upper surface of the array substrate 100 is stronger, and it is difficult for the second electrode 410 of the second electrode layer 400 to undergo edge upturning.

The shape of the surface of the planarization layer 110 toward the pixel definition layer 300 (i.e., the upper surface of the planarization layer 110) may be arranged in a variety of ways. For example, the upper surface of the planarization layer 110 is in a planar shape.

In some optional embodiments, the upper surface of the planarization layer 110 is in a planar shape, and the edge portion 440 of the second electrode 410 is disposed within the opening hole 330 and adheres to at least a part of the planarization layer 110 exposed by the opening hole 330. The distance between the edge portion 440 of the second electrode 410 and the first blocking layer 500 in the thickness direction of the display panel is less than the distance between the body portion 430 of the second electrode 410 and the first blocking layer 500 in the thickness direction of the display panel. The distance between the first blocking layer 500 and the edge portion 440 of the second electrode 410 is relatively small, the diffraction effect produced by the laser is relatively small, and in the process of laser etching, it is possible to effectively avoid the fold-over of the edge of the second electrode 410 toward the opening 420 caused by laser diffraction from affecting the encapsulation effect of the subsequent encapsulation process.

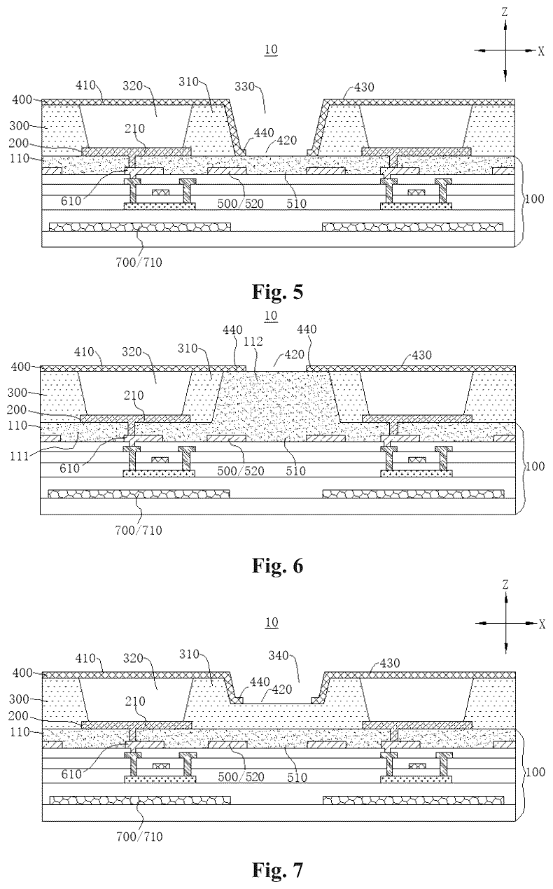

In other optional embodiments, as shown in FIG. 6, the planarization layer 110 includes a planarization portion 111 and a protruding portion 112 arranged as protruding from the planarization portion 111 and toward the opening hole 330. The edge portion 440 of the second electrode 410 contacts the protruding portion 112.

In these optional embodiments, the planarization layer 110 is provided with the protruding portion 112, and at least a part of the protruding portion 112 is disposed within the opening hole 330, so that a part of the second electrode layer 400 can be deposited on the protruding portion 112 when the second electrode layer 400 is deposited on the pixel definition layer 300, and a flatness of the second electrode layer 400 can be improved.

Optionally, a surface of a side of the protruding portion 112 close to the second electrode layer 200 and a surface of a side of the isolation portion 310 close to the second electrode layer 200 are in a same plane, which can further improve the flatness of the second electrode layer 400.

In some optional embodiments, an orthographic projection of the first through hole 510 in the thickness direction of the display panel is located within an orthographic projection of the opening hole 330 in the thickness direction of the display panel. Under a condition that the first blocking layer 500 is utilized to pattern the second electrode layer 400 to form the second electrode 410, due to the masking effect of the first blocking layer 500, the second electrode layer 400 in the region corresponding to the first through hole 510 forms the etched opening 420, and an unetched portion is the second electrode 410. The orthographic projection of the first through hole 510 in the thickness direction of the display panel is located within the orthographic projection of the opening hole 330 in the thickness direction of the display panel, then the edge portion 440 of the second electrode 410 toward the opening 420 is located within the opening hole 330, which can ensure that the distance between the edge portion 440 of the second electrode 410 and the first blocking layer 500 relatively small, and can better ameliorate the problem of the upturning of the edge of the second electrode 410 toward the opening 420.

In some optional embodiments, a plurality of pixel openings 320 are distributed in an array along the first direction X and the second direction Y, and the first through hole 510 is arranged between at least two adjacent columns of pixel openings 320.

Optionally, the first direction X is a column direction or a row direction, and the second direction Y is a column direction or a row direction. For example, under a condition that the second direction Y is the column direction, the first direction X is the row direction; under a condition that the second direction Y is the row direction, the first direction X is the column direction. The present application is illustrated with the first direction X being the row direction and the second direction Y being the column direction. The first direction X is perpendicular to the second direction Y.

In these optional embodiments, the plurality of pixel openings 320 are distributed in an array along the first direction X and the second direction Y, so as to ensure homogeneity of light emission. The first through hole 510 is arranged between regions corresponding to at least two adjacent columns of pixel openings 320, such that the region between the at least two adjacent columns of pixel openings 320 is used as an ashing region, and the laser light etches the second conductive material layer through the first through hole 510 to obtain the opening 420 of the second electrode layer 400.

In some optional embodiments, the first through hole 510 is arranged as extending along the second direction Y. The first through hole 510 extends along the second direction Y, such that between at least two adjacent columns of pixel openings 320, the laser light is able to etch the second conductive material layer through the first through hole 510 to obtain the opening 420 of the second electrode layer 400. In some optional embodiments, the first through hole 510 is arranged between any two adjacent columns of pixel openings 320.

In these optional embodiments, between any two adjacent columns of pixel openings 320, the laser light is able to etch the second conductive material layer through the first through hole 510 to obtain the opening 420 of the second electrode layer 400. As a result, it is possible to increase the distribution area of the opening 420, reduce the distribution area of the second electrode 410, and increase the light transmittance of the display panel 10.

In some optional embodiments, the opening hole 330 is arranged as extending along the second direction Y, and the opening hole 330 is arranged between any two adjacent columns of pixel openings 320. The light transmittance of the display panel 10 can be improved.

Please continue to refer to FIGS. 3 and 4, in some optional embodiments, the first blocking layer 500 further includes a plurality of first blocking portions 520 for blocking laser light and a first through hole 510 that allows the laser light to pass through, and at least a part of the first blocking portions 520 are arranged on two sides of the pixel opening 320 in the first direction X.

In these optional embodiments, the first blocking portions 520 arranged on two sides of the pixel opening 320 are used to form a first through hole 510 between adjacent pixel openings 320, and the laser light passes through the first through hole 510 to etch the second electrode layer 400, which can form the opening 420 on the second electrode layer 400. Therefore, the distribution area of the opening 420 can be increased, the distribution area of the second electrode 410 can be reduced, and the light transmittance of the display panel 10 can be improved.

Optionally, the first blocking layer 500 may further include a connection portion 530, and the connection portion 530 connects a plurality of first blocking portions 520.

In some optional embodiments, the first blocking portion 520 extends along the second direction Y. The first blocking portion 520 is a strip. Further, on two sides of each pixel opening 320, a first blocking portion 520 is arranged.

The first blocking portion 520 extends along the second direction Y and is arranged on two sides of the pixel opening 320, and the first through hole 510 formed by two first blocking portions 520 is arranged between two adjacent columns of pixel openings 320. The laser light passes through the first through hole 510 to etch the second electrode layer 400, which can form the opening 420 on the second electrode layer 400. In this process, the first blocking portion 520 plays the role of a mask plate. Through the above design, the distribution area of the opening 420 can be increased, the distribution area of the second electrode 410 can be reduced, and the light transmittance of the display panel 10 can be improved.

In some optional embodiments, the plurality of first mask portions 520 are arranged side by side along the first direction X, wherein the first direction X is parallel to the upper surface of the array substrate 100.

In these optional embodiments, the plurality of first blocking portions 520 are arranged side by side along the first direction X, such that a plurality of first through holes 510 extending along the second direction Y are formed in the first direction X. The laser light passes through the first through hole 510 to etch the second electrode layer 400, which can form the opening 420 on the second electrode layer 400. Therefore, the distribution area of the opening 420 can be increased, the distribution area of the second electrode 410 can be reduced, and the light transmittance of the display panel 10 can be improved.

Referring to FIG. 7, in some optional embodiments, the pixel definition layer 300 further includes a recess 340 located at the isolation portion 310, and the edge portion 440 of the second electrode 410 is located within the recess 340. Optionally, the edge portion 440 of the second electrode 410 contacts the bottom wall of the recess 340. Thus, the distance between the edge portion 440 of the second electrode 410 and the first blocking layer 500 in the thickness direction of the display panel is less than the distance between the body portion 430 of the second electrode 410 and the first blocking layer 500 in the thickness direction of the display panel. The distance between the first blocking layer 500 and the edge portion 440 of the second electrode 410 is relatively small, the diffraction effect produced by the laser is relatively small, and in the process of laser etching, it is possible to effectively avoid the fold-over of the edge of the second electrode 410 toward the opening 420 caused by laser diffraction from affecting the encapsulation effect of the subsequent encapsulation process.

In some optional embodiments, the body portion 430 of the second electrode 410 contacts the pixel definition layer 300, the edge portion 440 of the second electrode 410 is located within the recess 340 and contacts the pixel definition layer 300, and the adhesion force between the edge portion 440 and the pixel definition layer 300 is greater than the adhesion force between the body portion 430 and the pixel definition layer 300. Optionally, a plasma bombardment treatment may be performed on a part of the surface of the pixel definition layer 300 corresponding to the edge portion 440, such that a roughness of the part of the surface of the pixel definition layer 300 corresponding to the edge portion 440 rises, thereby causing the adhesion force between the edge portion 440 and the pixel definition layer 300 to be greater than the adhesion force between the body portion 430 and the pixel definition layer 300.

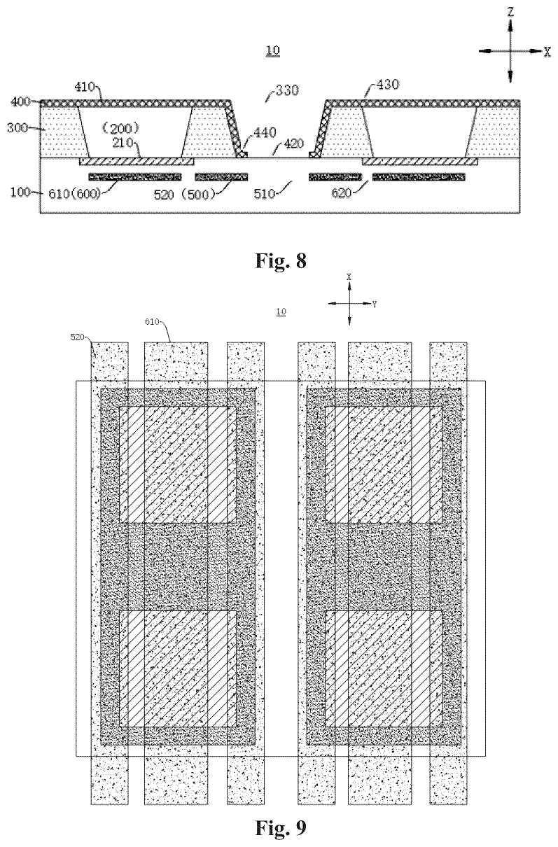

Referring to FIGS. 5 to 9 together, FIG. 8 is a cross-sectional view at A-A in FIG. 1 in yet another embodiment; and FIG. 9 is a local enlarged schematic structural view at Q in FIG. 1 in yet another embodiment.

In some optional embodiments, the array substrate 100 further includes a first metal layer 600, the first blocking layer 500 and the first metal layer 600 are arranged in a same layer, the first metal layer 600 includes a first metal line 610, and an orthographic projection of the pixel electrode 210 in the thickness direction of the display panel at least partially overlaps an orthographic projection of the first metal line 610 in the thickness direction of the display panel.

In these optional embodiments, the first blocking layer 500 is arranged in the same layer as the first metal layer 600 to simplify the preparation process. The first metal line 610 extends in the second direction Y and overlaps at least a part of the pixel electrodes 210, such that the pixel electrodes 210 are connected via the first metal line 610 for signal transmission, thereby ensuring that the light-emitting units emit light.

Optionally, the first metal line 610 connects the pixel electrodes 210, so that the pixel electrodes 210 can be connected to the driving circuit through the first metal line 610.

Optionally, a plurality of first metal lines 610 are arranged side by side along the first direction X, such that the plurality of columns of pixel electrodes 210 can be connected to the first metal lines 610 for signal transmission, thereby ensuring that the light-emitting units emit light.

Please continue to refer to FIG. 8, in some optional embodiments, a first gap 620 provided between the first blocking portion 520 and the first metal line 610.

In these optional embodiments, the first gap 620 enables the first blocking portion 520 and the first metal line 610 to be separated and insulated from each other, thereby avoiding damaging the first metal line 610 and affecting the electrical properties during the laser ashing of the second electrode layer 400.

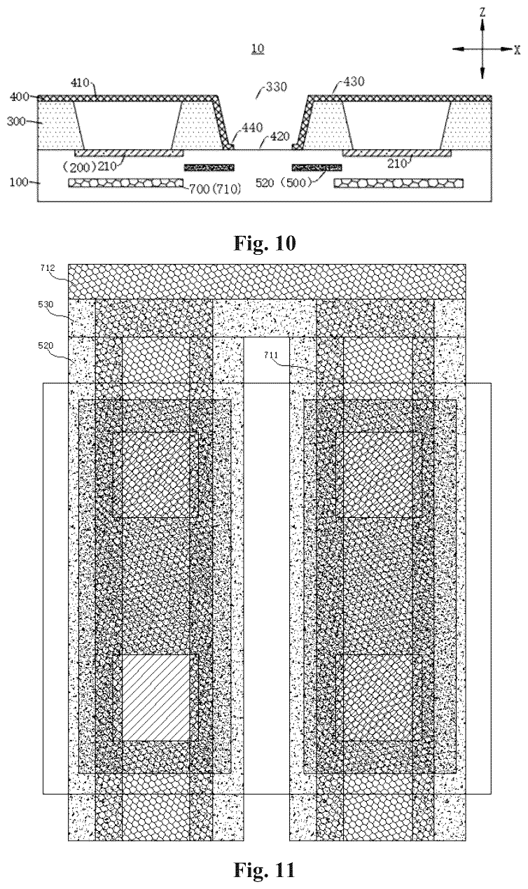

Referring together to FIGS. 10 and 11, FIG. 10 is a cross-sectional view of the display panel in yet another embodiment; and FIG. 11 is a local enlarged schematic structural view of the display panel in a further embodiment.

In some optional embodiments, the array substrate 100 further includes a second blocking layer 700, the second blocking layer 700 is arranged within the array substrate 100, the second blocking layer 700 includes a second blocking portion 710 for blocking the laser light, an orthographic projection of the first blocking portion 520 and the second blocking portion 710 in the thickness direction of the display panel overlaps an orthographic projection of the second electrode 410 in the thickness direction of the display panel. Such that, the first blocking portion 20 and the second blocking portion 710 can be used together as a mask plate for forming the second electrode layer 400 by patterning.

Optionally, the orthographic projection of the pixel opening 320 in the thickness direction of the display panel is located within the orthographic projection of the second blocking portion 710 in the thickness direction of the display panel.

In these optional embodiments, by providing the second blocking layer 700, when laser light is emitted toward the second electrode layer 400 from the side of the array substrate 100 away from the second electrode layer 400, the second blocking portion 710 of the second blocking layer 700 can block the laser light, thereby effectively avoiding the laser etching from damaging the pixel electrode 210 and the first metal line 610.

Optionally, the second blocking layer 700 is reused as an electrostatic shielding layer. For example, the second blocking layer 700 is a metallic shielding layer in the array substrate.

Optionally, as shown in FIG. 11, the orthographic projection of the edge of at least a part of the second blocking portions 710 in the thickness direction of the display panel is located within the orthographic projection of the first blocking portion 520 in the thickness direction of the display panel, such that there is no gap between the orthographic projections of the first blocking portion 520 and the second blocking portion 710 in the thickness direction of the display panel. Therefore, when laser etching the second conductive material layer, it is ensured that the etching region exists only between two adjacent first blocking portions 520.

In some optional embodiments, the second blocking portion 710 extends along the second direction Y, the second blocking portion 710 is a strip, and the orthographic projection of the edge of the second blocking portion 710 (parallel to the second direction Y) in the thickness direction of the display panel is located within the orthographic projection of the first blocking portion 520 in the thickness direction of the display panel.

Optionally, a plurality of second blocking portions 710 are arranged side by side along the first direction X.

Taking the second blocking portion 710 extending along the second direction Y and being a strip as an example, the orthographic projections of the pixel openings 320 in the thickness direction of the display panel are all located within the orthographic projections of the second blocking portions 710 in the thickness direction of the display panel. Further, through the blocking effect of the second blocking portion 710, the TFT device layer as well as a part of the array substrate 100 and light-emitting units are protected from the laser light. The orthographic projection of the edge of the second blocking portion 710 (parallel to the second direction Y) in the thickness direction of the display panel is located within the orthographic projection of the first blocking portion 520 in the thickness direction of the display panel, and the second blocking portion 710 overlaps the first blocking portion 520 in the first direction X, so that the region between the first blocking portion 520 and the pixel opening 320 is blocked by the second blocking portion 710, thereby avoiding laser damage to the pixel electrode 210, the first metal line 610 and other film layers caused by improper operations from affecting the display effect of the display panel.

Please continue to refer to FIG. 11, the shape of the second blocking portion 710 may be arranged in a variety of ways. In some optional embodiments, the second blocking portion 710 includes: a first sub-portion 711 extending along the second direction Y and being a strip, wherein a plurality of the first sub-portions 711 are arranged side by side along the first direction X; a second sub-portion 712 extending and molding along the first direction X and connecting the plurality of the first sub-portions 711 arranged side by side along the first direction X; wherein among a plurality of first gaps 620 and a plurality of opening holes 330 arranged side by side along the first direction X, at least a part of the orthographic projections of each of the first gaps 620 and the each of the opening holes 330 in the thickness direction of the display panel is located within the orthographic projection of the second blocking portion 710 in the thickness direction of the display panel.

In these optional embodiments, the first sub-portion 711 can block at least a part of each first gap 620 of a plurality of first gaps 620 located in a same column (under a condition that the first direction X is the row direction), and a part of the opening holes 330 is blocked by the second sub-portion 712, so that the second electrodes 410 in the same row or the same column can be interconnected. Through the blocking effect of the second sub-portion 712, the second electrodes 410 having the same distribution area and the same size as the second sub-portion 712 can be formed, so that the second electrodes 410 at different positions can be interconnected, a common electrode of the whole surface can be formed.

The location of the second sub-portion 712 may be arranged in a variety of ways. For example, under a condition that the display panel 10 includes a first region and a second region surrounding at least a part of the first region, the first sub-portion 711 is located in the first region, and the second sub-portion 712 is located in the second region, which can further reduce the distribution area of the second electrode 410 in the first region, and can improve the light transmittance of the first region. The first region may be a first display region AA1, the second region may be a non-display region, or the second region may be a second display region AA2.

Optionally, in the thickness direction Z of the display panel, the first blocking portion 520 is closer to the second electrode layer 400 than the second blocking portion 710, which can reduce the distance between the first blocking portion 520 and the second electrode layer 400, and can ameliorate the problem that the edge portion of the second electrode 410 of the second electrode layer 200 is prone to be upturned.

In some optional embodiments, the second electrode layer 400 further includes a connection portion for connecting the second electrodes 410, and an orthographic projection of the connection portion in the thickness direction of the display panel is located outside of the orthographic projection of the first through hole 510 in the thickness direction of the display panel. The connection portion may be formed by the second sub-portion 712.

In these optional embodiments, the connection portion enables the part of the second electrodes 410 corresponding to the two adjacent columns of pixel openings 320 in the first direction X to be interconnected to form a whole surface electrode, thereby facilitating the preparation of the second electrode layer 400.

Optionally, the first blocking layer 500 and/or the second blocking layer 700 may include a metal material, such as Mo (molybdenum). In some embodiments, the first blocking layer 500 and/or the second blocking layer 700 may be a metal composite material layer, such as Ti/Al/Ti (titanium/aluminum/titanium), ITO/Ag/ITO (indium tin oxide/silver/indium tin oxide), and the like.

It is worth illustrating that under a condition that the display panel 10 contains only the first blocking layer 500, it can be applied to a display panel for an under-screen camera, a stretchable display panel, a transparent display panel, and the like. For the display panel for the under-screen camera, the first blocking layer 500 can be present only in the first display region AA1. Furthermore, the first blocking layer 500 can be present in both the first display region AA1 and the second display region AA2.

Under a condition that the display panel 10 contains the first blocking layer 500 and the second blocking layer 700, it can also be applied to the display panel 10 for the under-screen camera, but in order to improve the light transmittance of the display panel 10, the first display region AA1 of the display panel 10 contains only the first blocking layer 500, and the second display region AA2 of the display panel 10 contains both the first blocking layer 500 and the second blocking layer 700; furthermore, it can also be applied to the stretchable display panel, and the transparent display panel.

Optionally, as shown in FIGS. 5 and 6, the orthographic projection of the second electrode 410 of the second electrode layer 400 along the thickness direction Z of the display panel is located within the orthographic projection of the second blocking layer 700 and the first blocking layer 500 along the thickness direction Z of the display panel, and the orthographic projection of the opening 420 along the thickness direction Z of the display panel is located within the orthographic projection of the first through hole 510 along the thickness direction Z of the display panel. That is, the first blocking layer 500 and the second blocking layer 700 can block all of the second electrode 410 in conjunction with each other, and when the laser ashing of the second electrode layer 400 is performed, the first blocking layer 500 and the second blocking layer 700 can block the laser light together to avoid the laser ashing of the second electrode 410.

For the structural design in this embodiment, it can be applied to other display panels 10, which can be selected according to the actual situation, and the present application does not impose specific limitations thereon.

The embodiments of the second aspect of the present application further provide a display device including the display panel 10 of any above embodiment of the first aspect. Since the display device provided by the embodiments of the second aspect of the present application includes the display panel 10 of any above embodiment of the first aspect, the display device provided by the embodiments of the second aspect of the present application has the beneficial effect that the display panel 10 of any above embodiment of the first aspect has, which will not be repeated herein.

The display device in the embodiments of the present application includes, but is not limited to, a cellular phone, a Personal Digital Assistant (PDA), a tablet computer, an e-book, a television set, a doorstop, an intelligent landline phone, a console, and other devices with display functions.

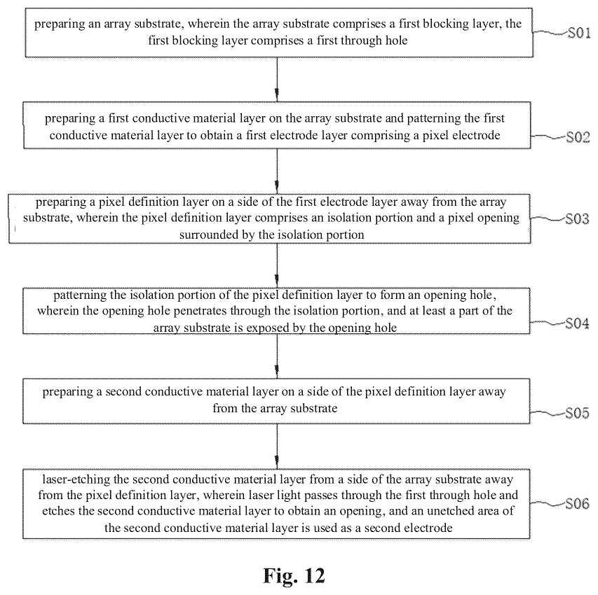

Referring to FIG. 12, FIG. 12 is a schematic flow diagram of a method of preparing a display panel provided by an embodiment of a third aspect of the present application. The display panel 10 may be the display panel 10 provided in any above embodiment of the first aspect.

As shown in FIG. 12, and please refer to FIGS. 1 to 11 together, the method of preparing the display panel 10 includes:

Step S01: preparing an array substrate 100, wherein the array substrate 100 includes a first blocking layer 500, the first blocking layer 500 includes a first through hole 510.

Step S02: preparing a first conductive material layer on the array substrate 100 and patterning the first conductive material layer to obtain a first electrode layer 200 including a pixel electrode 210.

Step S03: preparing a pixel definition layer 300 on a side of the first electrode layer 200 away from the array substrate 100, wherein the pixel definition layer 300 includes an isolation portion 310 and a pixel opening 320 surrounded by the isolation portion 310, and at least a part of the pixel electrodes 210 is exposed by the pixel opening 320.

Step S04: patterning the isolation portion 310 of the pixel definition layer 300 to form an opening hole 330, wherein the opening hole 330 penetrates through the isolation portion 310, and at least a part of the array substrate is exposed by the opening hole 330.

Step S05: preparing a second conductive material layer on a side of the pixel definition layer 300 away from the array substrate 100.

Step S06: laser-etching the second conductive material layer from a side of the array substrate 100 away from the pixel definition layer 300, wherein laser light passes through the first through hole 510 and etches the second conductive material layer to obtain an opening 420, and an unetched region of the second conductive material layer is used as a second electrode 410.

In the preparation method of the display panel 10 provided by the embodiments of the present application, the first blocking layer 500 is firstly prepared by step S01, and the pixel electrodes 210 can be prepared by step S02. Then, the pixel definition layer 300 is formed by step S03, so that the light-emitting unit can be arranged within the pixel opening 320, and the pixel electrodes 210 and the second electrodes 410 of the second electrode layer 400 can drive the light-emitting unit to emit light. The opening hole 330 arranged in the isolation portion 310 is prepared by step S04, and at least a part of the array substrate is exposed by the opening hole 330. The second conductive material layer is prepared by step S05 for forming the second electrode layer 400. The second electrode layer 400 includes the second electrode 410 and the opening 420. The first blocking layer 500 includes the first through hole 510. Further, the first blocking layer 500 is arranged within the array substrate 100, which can avoid affecting the display of the display panel 10. In the preparation process of the second electrode layer 400, the first blocking layer 500 can be utilized as a mask plate, and the opening 420 can be formed by emitting laser light from the side of the array substrate 100 away from the first electrode layer 200 through the first through hole 510 toward the second electrode layer 400. The orthographic projections of the first through hole 510 and the pixel electrode 210 in the thickness direction Z of the display panel are staggered, so as to avoid the laser light from etching the pixel electrodes 210 through the first through hole 510, which may affect the light-emitting display. On the one hand, the opening 420 is disposed in the second electrode layer 400, which can reduce the distribution area of the second electrode 410, thereby increasing the light transmittance of the display panel 10. On the other hand, the distance between the first blocking layer 500 and the second electrode layer 400 is relatively small, which can effectively avoid the fold-over of the edge of the second electrode 410 toward the opening 420 caused by laser diffraction from affecting the encapsulation effect of the subsequent encapsulation process.

In step S04, the isolation portion 310 on the pixel definition layer 300 may also be patterned to form the opening hole 330, that is, the isolation portion may be patterned to form the opening hole 330. Optionally, the orthographic projection of the opening 420 on the array substrate is located within the orthographic projection of the opening hole 330 on the array substrate 100. Optionally, the opening hole 330 penetrates through the isolation portion, and at least a part of the array substrate 100 is exposed by the opening hole 330. No light-emitting unit is disposed within the opening hole 330, and under a condition that a common layer such as a hole injection layer, a hole transport layer, an electron transport layer, and an electron injection layer is disposed on the pixel definition layer 300, the common layer can be removed when forming the opening hole 330, thereby allowing the second electrode 410 of the second electrode layer 400 to be in direct contact with the array substrate 100 exposed by the opening hole 330, and further reducing the distance between the second electrode layer 400 and the first blocking layer 500. When the second conductive material layer is formed in step S05, there will be no structure such as the isolation portion 310 between the second conductive material layer and the first blocking layer 500, which can further reduce the distance between the second conductive material layer and the first blocking layer 500 in the region where the opening hole 330 is located. In step S06, when patterning the second conductive material layer by using the first blocking layer 500 as a mask plate, due to the distance between the second conductive material layer and the first blocking layer 500 being relatively small, it is possible to improve diffraction and avoid the upturning of the edge portion 440 of the second electrode 410, which in turn avoids affecting the yield of the subsequent encapsulation process.

Optionally, in step S02, the preparation method further includes: performing a wet etching process on the first conductive material layer to obtain pixel electrodes 210 that are spaced apart, and causing at least a part of the array substrate 100 to be exposed by a gap between two adjacent pixel electrodes 210. The pixel electrodes 210 are prepared by the wet etching process, so that the roughness of the upper surface of the array substrate 100 exposed by the gap between the two adjacent pixel electrodes 210 rises, and in the subsequent preparation of the second electrode layer 400, the second conductive material layer can be directly deposited on the upper surface of the array substrate 100 exposed by the gap between the two adjacent pixel electrodes 210. Further, the roughness of the upper surface of that portion of the array substrate 100 rises, so that the adhesion force between the second electrode 410 of the second electrode layer 400 and the upper surface of the array substrate 100 is stronger, and it is difficult for the second electrode 410 of the second electrode layer 400 to undergo edge upturning.

Optionally, the array substrate 100 includes a planarization layer 110, and in step S03, at least a part of the planarization layer is exposed by the opening hole 330.

In step S02, the preparation method further includes: preparing the first conductive material layer on the planarization layer 110, performing a wet etching process on the first conductive material layer to obtain pixel electrodes 210 that are spaced apart, and causing at least a part of the planarization layer 110 to be exposed by a gap between two adjacent pixel electrodes 210. The pixel electrodes 210 are prepared by the wet etching process, such that the roughness of the upper surface of the part of the planarization layer 110 exposed by the gap between the two adjacent pixel electrodes 210 rises, and in the subsequent preparation of the second electrode layer 400, the second conductive material layer can be directly deposited on the upper surface of the part of the planarization layer 110 exposed by the gap between the two adjacent pixel electrodes 210, that is, the second conductive material layer directly contacts the at least a part of the planarization layer 110 exposed by the opening hole 330. Further, the roughness of the upper surface of the planarization layer 110 is relatively high, so that the adhesion force between the second electrode 410 of the second electrode layer 400 and the upper surface of the planarization layer 110 is stronger, and it is difficult for the second electrode 410 of the second electrode layer 400 to undergo edge upturning.

According to the embodiments of the present application as described above, these embodiments do not describe all the details and do not limit the present application to the specific embodiments as described. Obviously, there are many modifications and changes that can be made based on the above description. This specification selects and describes these embodiments in order to better explain the principle and practical application of the present application, so that those skilled in the art can make good use of the present application and the modification of the present application. The present application is limited only by the claim and its full scope and equivalents.

What is claimed is:

1. A display panel, comprising:
an array substrate;
a first electrode layer located on a side of the array substrate and comprising a pixel electrode;
a pixel definition layer located on a side of the first electrode layer away from the array substrate and comprising an isolation portion, a pixel opening defined by the isolation portion and an opening hole located at the isolation portion, and at least a part of the array substrate exposed from the opening hole;
a second electrode layer located on a side of the pixel definition layer away from the array substrate, the second electrode layer comprising a second electrode and an opening, the second electrode comprising a body portion and an edge portion extending from the body portion and toward the opening, and the edge portion contacts the at least a part of the array substrate exposed by the opening hole.

2. The display panel according to claim 1, wherein the body portion of the second electrode contacts the pixel definition layer, and an adhesion force between the edge portion of the second electrode and the at least a part of the array substrate exposed from the opening hole is greater than an adhesion force between the body portion and the pixel definition layer;
the pixel electrode is formed by a wet etching process.

3. The display panel according to claim 1, wherein the opening hole of the pixel definition layer penetrates through the isolation portion, and the edge portion is located within the opening hole and is adhered to the at least a part of the array substrate exposed from the opening hole.

4. The display panel according to claim 1, wherein the array substrate comprises a planarization layer, at least a part of the planarization layer is exposed from the opening hole, and the edge portion contacts the at least a part of the planarization layer exposed from the opening hole.

5. The display panel according to claim 4, wherein the planarization layer comprises a planarization portion and a protruding portion protruding from the planarization portion and toward the opening hole, and the edge portion is contacted with the protruding portion.

6. The display panel according to claim 5, wherein a surface of a side of the protruding portion close to the second electrode layer and a surface of a side of the isolation portion close to the second electrode layer are in a same plane.

7. The display panel according to claim 1, wherein the array substrate comprises a first blocking layer, the first blocking layer comprises a plurality of first blocking portions for blocking laser light and a first through hole that allows the laser light to pass through; an orthographic projection of the first through hole in a thickness direction of the display panel overlaps an orthographic projection of the opening of the second electrode layer in the thickness direction of the display panel.

8. The display panel according to claim 7, wherein a plurality of pixel openings are distributed in an array along a first direction and a second direction, the first direction is a row direction, the second direction is a column direction, and the first direction is perpendicular to the second direction, the opening hole is arranged as extending along the second direction; and the opening hole is arranged between two adjacent columns of the pixel openings.

9. The display panel according to claim 8, wherein the plurality of first blocking portions are arranged side by side along the first direction and the first blocking portion is a strip and extends along the second direction.

10. The display panel according to claim 7, wherein the array substrate comprises a first metal layer, the first blocking layer and the first metal layer are arranged in a same layer, the first metal layer comprises a plurality of first metal lines; an orthographic projection of the pixel electrode in the thickness direction of the display panel at least partially overlaps an orthographic projection of the first metal line in the thickness direction of the display panel;
the plurality of first metal lines are arranged side by side along the first direction;
a first gap is provided between the first blocking portion and the first metal line.

11. The display panel according to claim 7, wherein the array substrate further comprises a second blocking layer, the second blocking layer comprises a second blocking portion for blocking the laser light, an orthographic projection of the first blocking portion and the second blocking portion in the thickness direction of the display panel overlaps an orthographic projection of the second electrode in the thickness direction of the display panel, and the first blocking portion is closer to the second electrode layer than the second blocking portion in the thickness direction of the display panel;
the second blocking layer is reused as an electrostatic shielding layer.

12. A display panel, comprising:
an array substrate;
a first electrode layer located on a side of the array substrate and comprising a pixel electrode;
a pixel definition layer located on a side of the first electrode layer away from the array substrate and comprising an isolation portion and a pixel opening surrounded by the isolation portion;
a second electrode layer located on a side of the pixel definition layer away from the array substrate and comprising a second electrode and an opening;
wherein the second electrode comprises a body portion and an edge portion arranged as extending from the body portion and toward the opening, the body portion contacts the pixel definition layer, the edge portion contacts the array substrate or the pixel definition layer, and an adhesion force between the edge portion and the array substrate or the pixel definition layer is greater than an adhesion force between the body portion and the pixel definition layer.

13. The display panel according to claim 12, wherein the array substrate comprises a planarization layer, the pixel definition layer further comprises an opening hole located at the isolation portion, at least a part of the planarization layer is exposed by the opening hole, the edge portion contacts the at least a part of the planarization layer exposed by the opening hole, and an adhesive force between the edge portion and the planarization layer is greater than the adhesive force between the body portion and the pixel definition layer.

14. A display panel, comprising:
an array substrate, wherein the array substrate comprises a first blocking layer, and the first blocking layer comprises a first through hole;
a first electrode layer located on a side of the array substrate, wherein the first electrode layer comprises a pixel electrode;
a pixel definition layer located on a side of the first electrode layer away from the array substrate, wherein the pixel definition layer comprises an isolation portion and a pixel opening surrounded by the isolation portion;
a second electrode layer located on a side of the pixel definition layer away from the array substrate, wherein the second electrode layer comprises a second electrode and an opening, the second electrode comprises a body portion and an edge portion arranged as extending from the body portion and toward the opening;
wherein an orthographic projection of the first through hole in a thickness direction of the display panel overlaps an orthographic projection of the opening in the thickness direction of the display panel, a distance between the edge portion and the first blocking layer in the thickness direction of the display panel is less than a distance between the body portion and the first blocking layer in the thickness direction of the display panel.

15. The display panel according to claim 14, wherein the pixel definition layer further comprises an opening hole located at the isolation portion, at least a part of the array substrate is exposed by the opening hole, and the edge portion contacts the at least a part of the array substrate exposed by the opening hole.

16. The display panel according to claim 14, wherein the pixel definition layer further comprises a recess located at the isolation portion, and the edge portion is located within the recess;
the edge portion contacts a bottom wall of the recess.

17. A display device, comprising the display panel according to claim 1.
